(19) United States
(12) Patent Application Publication
(10) Pub. No.: US 2026/0005073 A1
(43) Pub. Date: Jan. 1, 2026

(54) METHODS FOR ELECTRICAL PROPERTY DEPTH PROFILING THROUGH FILMS WITH GRADED COMPOSITION

(71) Applicant: Active Layer Parametrics, Inc., Scotts Valley, CA (US)

(72) Inventors: Bulent M. BASOL, Manhattan Beach, CA (US); Abhijeet JOSHI, Scotts Valley, CA (US)

(21) Appl. No.: 18/759,553

(22) Filed: Jun. 28, 2024

(51) Int. Cl. H01L 21/66; G01B 7/06

(52) U.S. Cl. CPC H01L 22/14; G01B 7/105

(57) ABSTRACT

A method of obtaining a depth profile of an electrical property through a film with a composition varying as a function of depth is disclosed.

### FIELD OF THE INVENTION

The present inventions are in the field of thin film electrical characterization methods and apparatus. More particularly, the present inventions provide methods and tools for electrical characterization of layers and interfaces employed in advanced semiconductor device structures.

### BACKGROUND OF THE INVENTION

With the advancement of the semiconductor industry, electronic devices such as integrated circuits get more and more miniaturized and they employ ultra-shallow junctions in semiconductor layers. For the advanced sub-7 nm node technologies devices may have source/drain junctions that are extremely shallow, i.e., less than about 30 nm deep. To reduce contact resistance such films may comprise extremely high total dopant concentrations (e.g., >10²¹ cm⁻³), especially near the semiconductor film surface. All of these dopants, however, may not be active. To be able to develop and optimize such advanced device structures, it is essential to accurately measure the electrical properties or parameters of extremely thin semiconductor layers and understand how such properties may change through the thickness of the layers. Specifically, it is important to know the degree of dopant activation within the top 5-10 nm of the surface region of such layers. This requires obtaining accurate, well calibrated carrier concentration depth profiles with a depth resolution of smaller than 1 nm.

Some of the materials used in advanced device structures are in the form of alloys comprising two or more constituent elements. For example, SiGe alloys with various Ge content are important materials for transistor applications. Furthermore, optimization of a structure employing SiGe materials may require the Ge content to be graded, i.e. varying as a function of depth. Film stacks to be measured may also comprise materials that may be compositionally different from each other. Metal/semiconductor, semiconductor/semiconductor and insulator/semiconductor structures are examples of such films. Depth profiles of electrical parameters or properties through such complex structures need to be measured to understand and optimize their electrical performance.

Some prior-art electrical property depth profiling techniques have utilized a repetitive process sequence that involved anodic oxide formation at a test site on a semiconductor film body, removal of the oxide layer by chemical etching, rinsing, drying and then measuring an electrical parameter by contacting the test site with electrical contact probes (see for example U.S. Pat. Nos. 3,554,891 and 3,660,250). Such techniques are not suitable for accurate measurements on extremely thin layers employed in advanced device structures.

Another technique for generating a depth profile of electrical properties through a semiconductor substrate was disclosed in U.S. Pat. No. 7,078,919. In that approach, a process was used to form an anodic oxide film over the surface of the semiconductor substrate using an electrolyte and a cathode. Thickness of the anodic oxide film was increased in a stepwise manner. After each oxidation step, measurement of the electrical properties of the semiconductor substrate under the anodic oxide film was carried out without removing the electrolyte from the exposed surface of the anodic oxide film. In this technique a constant anodic current was applied between the cathode and the semiconductor substrate to convert a layer of the semiconductor substrate into anodic oxide. The depth or the thickness of the anodic oxide was reported to be proportional to a forming voltage (V-Vo) with a linear relationship and a constant slope, where V is the voltage required to maintain the constant anodic current and Vo was an onset voltage. This approach may be used to measure compositionally uniform films. However, it may not be suited for characterization of a more complex layer with a composition that may vary as a function of depth through the layer.

Therefore, new methods with capability to accurately and reliably depth profile electrical properties or parameters of layers comprising different materials with different compositions are required.

### BRIEF DESCRIPTION OF THE DRAWINGS

FIG. 1 is a cross-sectional side view of an exemplary process head.

FIG. 2A shows a top view of a cross-shaped test pattern comprising a graded film with a top surface to be characterized by obtaining a depth profile of its electrical property, the test pattern comprising a test region.

FIG. 2B shows a cross-sectional side view of the structure shown in FIG. 2A.

FIG. 3 shows a cross-sectional side view of the exemplary process head of FIG. 1 pressed and sealed against the top surface of the graded film of FIG. 2A and FIG. 2B, forming an enclosed mini chamber over the test region.

FIG. 3A shows a close-up view of the graded film at the test region.

FIG. 3B shows formation of a first oxide layer and a first residual film at the test region after a first oxidation step.

FIG. 3C shows formation of a second oxide layer and a second residual film at the test region after a second oxidation step.

FIG. 3D shows formation of a third oxide layer and a third residual film at the test region after a third oxidation step.

FIG. 4 shows an exemplary compositional depth profile for the graded film wherein a compositional ratio changes through the film as a function of depth.

FIG. 5 shows an exemplary conversion factor for the graded film conversion factor changing as a function of the compositional ratio of FIG. 4.

FIG. 6 shows an exemplary conversion factor as a function of depth for a metal/semiconductor structure.

### DETAILED DESCRIPTION OF THE INVENTION

Present inventions provide methods and apparatus for measurement of an electrical property depth profile through a compositionally graded film (also called graded film). The graded film may comprise an alloy semiconductor with its composition changing as a function of depth. The graded film may also comprise different materials in the form of stacks. Examples of graded films include, but are not limited to, alloy films, metal/semiconductor configurations, semiconductor/semiconductor structures comprising dissimilar semiconducting materials, and insulator/semiconductor structures. The graded film to be characterized may be disposed over a substrate such as a wafer. There may be an insulating interface between the graded film and the substrate. The electrical property may include sheet resistance, sheet conductance, resistivity, conductivity, Hall voltage, sheet Hall coefficient, mobility and carrier concentration.

A profiling tool may be used to obtain the depth profile of the electrical property. The profiling tool may comprise a substrate holder, at least one process head, a mechanism that may provide relative motion between the substrate holder and the at least one process head, a source providing at least one process solution, a pumping and plumbing system to deliver and remove the at least one process solution to and from the at least one process head, a power supply that is used to apply oxidation potentials for anodic oxidation processes, an electrical measurement system, a control system and a computer system configured to control all functions of the tool and carry out the required calculations.

As an example, FIG. 1 shows a process head 200 constructed in accordance with a preferred embodiment of the present inventions. The process head 200 may comprise a process cavity 202 with an open end 202A, an electrode 203 exposed to the process cavity 202, an inlet 204 and an outlet 205 that may be connected to the process cavity 202 and configured to flow a process solution into and out of the process cavity 202. The electrode 203 may comprise a conductive inert material such as platinum. A sealing member 201 with a bottom surface 201A is provided along the edge of the open end 202A of the process cavity 202. The sealing member 201 may preferably be made of an elastomer.

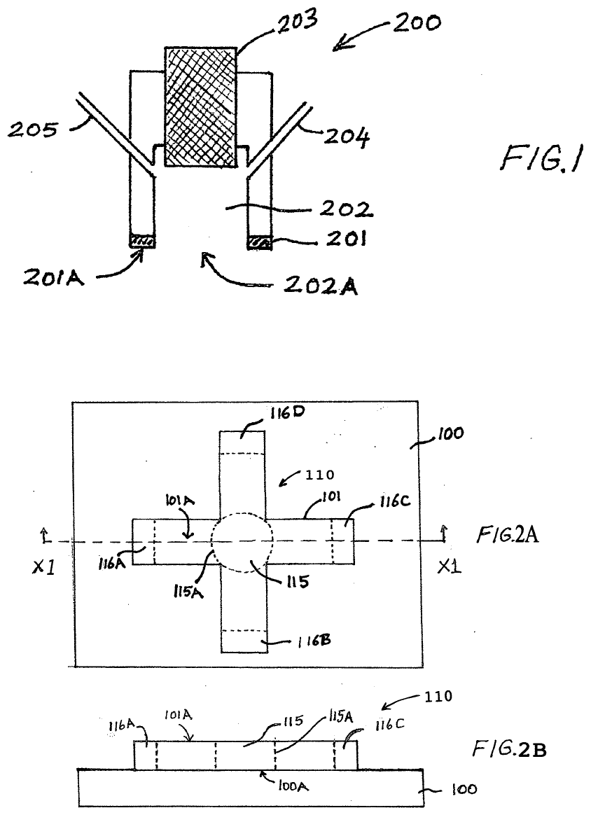

In a preferred embodiment, a step in obtaining a depth profile of an electrical property through a graded film employing the teachings of the present inventions may be to construct a test pattern comprising the graded film. FIG. 2A shows a top view of a test pattern 110 comprising a graded film 101 to be characterized. FIG. 2B shows a cross-sectional side view of the structure in FIG. 2A, taken along the line X1-X1. As can be seen from FIG. 2A and FIG. 2B, the graded film 101 may be disposed over a substrate 100, and it may have an original top surface 101A. The test pattern 110 may be in the form of a cross, although there are other acceptable shapes. The graded film 101 may be electrically isolated from the substrate 100 by an insulating interface 100A, which may be a thin insulating layer or a rectifying electrical junction, such as a p-n junction, that may not allow any substantial portion of an electric test current to flow through the substrate 100 when the electric test current is passed between any two points on the test pattern 110. The test pattern 110 may comprise a test region 115 with a test region circumference 115A, and at least two electrical contact regions configured such that entirety of the electric test current passed between any two electrical contact regions passes through the test region 115, and the at least two electrical contact regions are outside the test region 115. As shown in FIG. 2A, the test pattern 110 may comprise a first electrical contact region 116A, a second electrical contact region 116B, a third electrical contact region 116C, and a fourth electrical contact region 116D. It should be noted that the electrical contact regions may be contacted by probes that may connect them to power supplies or measurement instruments to apply power to the graded film 101 and to carry out voltage and current measurements.

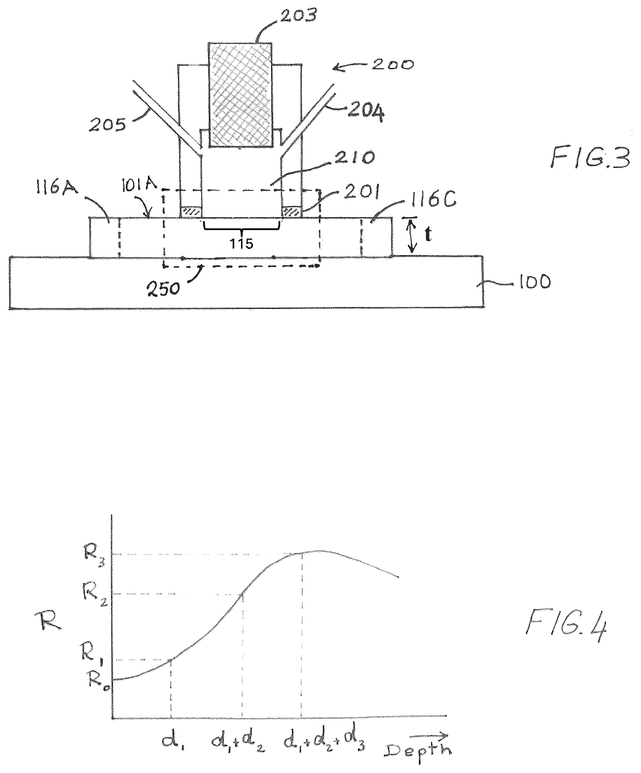

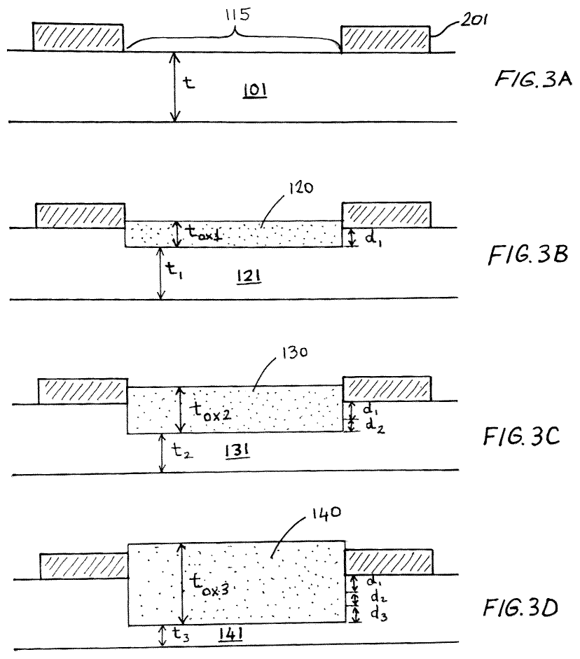

As shown in FIG. 3, the open end 202A of the process cavity 202 of the process head 200 (see also FIG. 1) may be pressed and sealed against the original top surface 101A of the graded film 101, forming an enclosed mini chamber 210 over the test region 115 such that a fluid flown into the enclosed mini chamber 210 may touch and cover the entire test region 115, without touching any part of the original top surface 101A outside the test region 115. In this example, the graded film 101 may have a thickness “t”. The test region circumference 115A (FIG. 2A) may be defined by the sealing member 201.

FIG. 3A, FIG. 3B, FIG. 3C and FIG. 3D illustrate enlarged views of a section 250 shown in FIG. 3, and they demonstrate a sequence of procedures that may be carried out for determining a depth profile of an electrical property through the graded film 101 at the test region 115. First, an initial measurement step may be carried out during an initial measurement period (FIG. 3 and FIG. 3A) when an initial sheet resistance and an initial sheet Hall coefficient may be determined for the graded film 101. Determining the initial sheet resistance may comprise passing an initial resistance test current from the first electrical contact region 116A to the fourth electrical contact region 116D through the graded film 101 at the test region 115, and measuring an initial resistance voltage drop between the second electrical contact region 116B and the third electrical contact region 116C. The initial resistance test current and the initial resistance voltage drop values may then be used to calculate the initial sheet resistance using the Van der Pauw equations (see, for example, ASTM Standard F76-08 (2016) “Standard test methods for measuring resistivity and Hall coefficient and determining Hall mobility in single crystal semiconductors”). For determining the initial sheet Hall coefficient, an initial mobility test current may be passed from the first electrical contact region 116A to the third electrical contact region 116C through the graded film 101 at the test region 115. An initial Hall voltage may be measured between the second electrical contact region 116B and the fourth electrical contact region 116D after a magnetic field is applied perpendicular to the top surface 101A. The initial sheet Hall coefficient, which is equal to the initial Hall voltage divided by the magnetic field strength and the initial mobility test current, may then be calculated using this data.

A first process solution may be flown into the enclosed mini chamber 210 through the inlet 204 and delivered onto the test region 115. The first process solution may substantially fill the enclosed mini chamber 210 touching both the test region 115 and the electrode 203 (see FIG. 3). Once the first process solution is flown into the enclosed mini chamber 210, a first oxidation potential may be applied between the electrode 203 and the test region 115 (preferably through at least one of the four electrical contact regions), during a first oxidation period. The first oxidation potential may render the test region 115 anodic (more positive) with respect to the electrode 203 and may pass a first oxidation current between the test region 115 and the electrode 203. As can be seen in FIG. 3B, during the first oxidation period a first slice of the graded film 101 at the test region 115 may be converted into oxide by anodic oxidation, forming a first oxide layer 120, and leaving behind a first residual film 121 with a first top surface. The first slice of the graded film 101 converted into oxide may have a thickness “d₁”. The thickness of the first oxide layer 120 may be “tₒₓ₁” and the thickness of the first residual film 121 may be “t₁”. As seen in FIG. 3B, the first top surface is near an interface between the first oxide layer 120 and the first residual film 121. In other words, the first top surface may be deeper than the original top surface by “d₁”.

In an exemplary measurement sequence, the first oxidation potential may be removed at the end of the first oxidation period. A first measurement step may be carried out during a first measurement period following the first oxidation period. During the first measurement period, a first sheet resistance and a first sheet Hall coefficient may be determined for the first residual film 121. Determining the first sheet resistance may comprise passing a first resistance test current from the first electrical contact region 116A to the fourth electrical contact region 116D through the first residual film 121 at the test region 115, and measuring a first resistance voltage drop between the second electrical contact region 116B and the third electrical contact region 116C. This data may then be used to calculate the first sheet resistance using the Van der Pauw equations. For determining the first sheet Hall coefficient, a first mobility test current may be passed from the first electrical contact region 116A to the third electrical contact region 116C through the first residual film 121 at the test region 115. A first Hall voltage may be measured between the second electrical contact region 116B and the fourth electrical contact region 116D after a magnetic field is applied perpendicular to the top surface 101A. The first sheet Hall coefficient, which is equal to the first Hall voltage divided by the magnetic field and the first mobility test current, may be calculated using this data.

After the first measurement period, a second oxidation potential, which may be larger than the first oxidation potential, may be applied between the electrode 203 and the test region 115, during a second oxidation period, in presence of a second process solution over the test region 115. The second process solution may or may not be the same as the first process solution. The second oxidation potential may render the test region 115 anodic with respect to the electrode 203 and may pass a second oxidation current between the test region 115 and the electrode 203. As can be seen in FIG. 3C, during the second oxidation period a second slice of the graded film 101 at the test region 115 may be converted into oxide by anodic oxidation. This process may increase the thickness of the first oxide layer 120 thus producing a second oxide layer 130 and leaving behind a second residual film 131 with a second top surface. The second slice of the graded film 101 converted into oxide may have a thickness “d₂”, the thickness of the second oxide layer may be “tₒₓ₂”, and the thickness of oxide generated during the second oxidation period may be (tₒₓ₂−tₒₓ₁). As seen in FIG. 3C, the second top surface is near an interface between the second oxide layer 130 and the second residual film 131. In other words, the second top surface may be deeper than the original top surface by “d₁+d₂”.

The second oxidation potential may be removed at the end of the second oxidation period, and a second measurement step may be carried out during a second measurement period. During the second measurement period, a second sheet resistance and a second sheet Hall coefficient may be determined for the second residual film 131, following steps that are like those discussed for determination of the first sheet resistance and the first Hall coefficient for the first residual film 121.

After the second measurement period, a third oxidation potential, which may be larger than the second oxidation potential, may be applied between the electrode 203 and the test region 115, during a third oxidation period, in presence of a third process solution over the test region 115. The third process solution may or may not be the same as the second process solution. The third oxidation potential may render the test region 115 anodic with respect to the electrode 203 and may pass a third oxidation current between the test region 115 and the electrode 203. As can be seen in FIG. 3D, during the third oxidation period a third slice of the graded film 101 at the test region 115 may be converted into oxide by anodic oxidation. This process may increase the thickness of the second oxide layer 130 thus producing a third oxide layer 140 and leaving behind a third residual film 141 with a third top surface. The third slice of the graded film 101 converted into oxide may have a thickness “d₃”, the thickness of the third oxide layer may be “tₒₓ₃”, and the thickness of oxide generated during the third oxidation period may be (tₒₓ₃−tₒₓ₂). As seen in FIG. 3D, the third top surface is near an interface between the third oxide layer 140 and the third residual film 141. In other words, the third top surface may be deeper than the original top surface by “d₁+d₂+d₃”.

The third oxidation potential may be removed at the end of the third oxidation period and a third measurement step may be carried out during a third measurement period. During the third measurement period, a third sheet resistance and a third sheet Hall coefficient may be determined for the third residual film 141, following steps that are like those discussed for determination of the first sheet resistance and the first Hall coefficient for the first residual semiconductor film 121.

The above-mentioned anodic oxidation and measurement steps may be repeated and a depth profile of properties such as sheet resistance, resistivity, mobility and carrier concentration through the graded film 101 may be obtained using differential relationships, and sheet resistance and sheet Hall coefficient data collected, provided that accurate values for the thicknesses (d₁, d₂, d₃ . . . ) of the slices of materials converted into oxide during each of the oxidation periods may be determined.

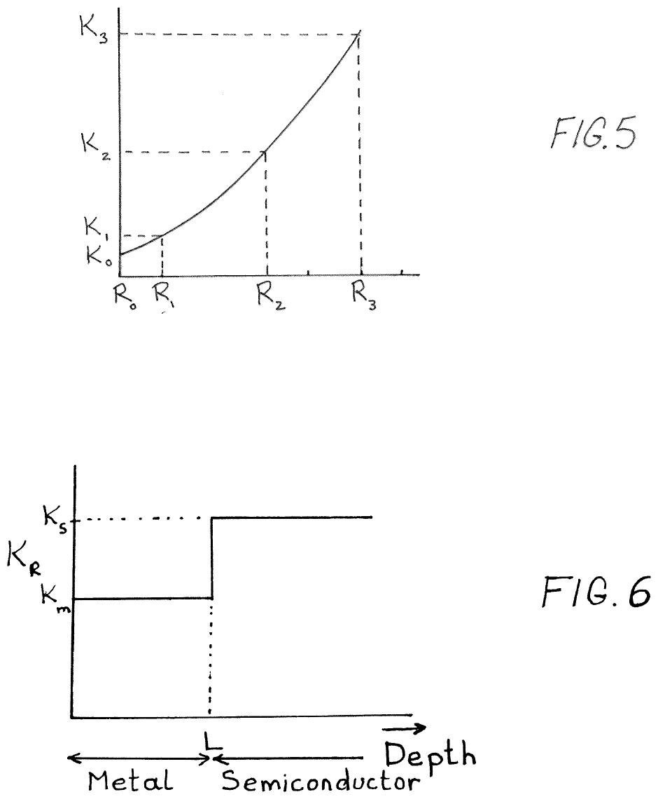

Let us take as an example a case wherein the graded film 101 depicted in FIG. 3A is an alloy film represented by the chemical formula XY, where X and Y are the two constituent elements of the alloy. An example of such an alloy may be a SiGe alloy, where X=Si and Y=Ge. A composition of the graded film 101 of this example may be represented by a compositional ratio, R=Y/(X+Y), which may change as a function of depth. FIG. 4 shows an example compositional depth profile for the graded film 101. As can be seen from this figure, R may first increase going from the surface deeper into the film and then it may decrease again. It should be noted that such compositional depth profiles may be obtained for any graded layer using methods such as secondary ion mass spectrometry (SIMS).

Referring to FIG. 3B, FIG. 3C and FIG. 3D the thicknesses, d₁, d₂ and d₃ of film slices converted into oxide may be determined using; i) oxide voltage values at the end of each oxidation step, ii) compositional ratios at depths 0, d₁ and d₂, and iii) conversion factors at depths 0, d₁ and d₂. When an alloy, XY, is anodically oxidized, the thickness of a slice of the alloy consumed to form an oxide layer may be related to the voltage across the formed oxide layer by the equation (T=K_{R} Vₒₓ), where T is the thickness of the alloy film slice consumed to form the oxide layer in units of angstrom (Å), K_{R} is a conversion factor (in units of Å/V) near the depth where oxidation takes place, and Vₒₓ is the voltage across the oxide layer (in units of Volt) at the end of anodic oxidation. It should be noted that in the case of a graded film or a graded alloy film, K_{R} may not be a constant, but it may be a function of the compositional ratio R. Therefore, while characterizing the graded film 101 in this example, one may consider how R may be changing through the film, before the thicknesses of the alloy film slices consumed to form the oxide layers during each oxidation period may be determined.

FIG. 5 shows an example of a conversion factor K_{R} as a function of the compositional ratio R for the graded film 101. K_{R} vs. R relationship may be predetermined and established by anodic oxidation of a series of uniform alloy films with no compositional grading, and by measuring oxide voltages, oxide thicknesses, and thicknesses of the film slices consumed during each oxidation. Such measurements may be carried out using techniques such as TEM and the K_{R} vs. R relationship may be established for alloys with different compositions. For example, to establish K_{R} vs. R relationship for SiGe alloys, one may start with a film with uniform Ge concentration and a Ge/(Si+Ge) ratio of 0.1. After anodic oxidation, a relationship may be determined between the oxide voltage across the anodic oxide and the thickness of the Si_{0.9}Ge_{0.1} slice converted into oxide. This provides the K_{R} for the Si_{0.9}Ge_{0.1} alloy with R=0.1. Measurements may then be repeated for uniform composition films with R values of 0.2, 0.3, 0.4, etc. and thus K_{R} vs. R relationship may be established or configured.

While determining an electrical property depth profile for the graded film 101 using the characterization tools and teachings of the present inventions, the value of R at a certain depth of the graded film 101 may be provided to a program or algorithm of the characterization tool (see FIG. 4) and the predetermined value of the conversion factor K_{R} corresponding to that R value may also be supplied to the program or algorithm of the characterization tool (see FIG. 5). Therefore, during depth profiling an electrical property through such a film, after each oxidation step the values of R and K_{R} at around that depth may be used to determine the thickness of the slice of the film that got oxidized. This thickness value may then be used to calculate the electrical property of the graded film 101 at that depth.

Referring to FIG. 3B, at the end of the first oxidation period a first oxide voltage Vₒₓ₁ may be determined. It should be noted that the first oxide voltage Vₒₓ₁, which is the voltage across the first oxide layer 120, may not be equal to the first oxidation potential applied between the electrode 203 and the test region 115 during the first oxidation period. This is because there may be a first external resistance (due to electrolyte, wiring and electrode/electrolyte interface, etc.) across which a first external voltage drop may develop. The first external voltage drop may be determined by multiplying the first oxidation current with the first external resistance, and it may be deducted from the first oxidation potential to determine Vₒₓ₁. Once Vₒₓ₁ is determined, the value of d₁ may be calculated using the relationship d₁=K₀Vₒₓ₁. This is because the compositional ratio near the original top surface 101A of the graded film 101 where oxidation is initiated is R₀ (see FIG. 4) and the K_{R} value corresponding to this composition is K₀ (see FIG. 5).

Referring to FIG. 3C, at the end of the second oxidation period a second oxide voltage Vₒₓ₂ may be determined. It should be noted that the second oxide voltage Vₒₓ₂, which is the voltage across the second oxide layer 130, may not be equal to the second oxidation potential applied between the electrode 203 and the test region 115 during the second oxidation period. This is because there may be a second external resistance across which a second external voltage drop may develop. The second external voltage drop may be determined by multiplying the second oxidation current with the second external resistance, and it may be deducted from the second oxidation potential to determine Vₒₓ₂. Once Vₒₓ₂ is determined, the value of d₂ may be calculated using the relationship d₂=K₁ (Vₒₓ₂−Vₒₓ₁). This is because the compositional ratio near the first top surface where oxidation is initiated is R₁ (see FIG. 4) and the K_{R} value corresponding to this composition is K₁ (see FIG. 5).

Referring to FIG. 3D, at the end of the third oxidation period a third oxide voltage Vₒₓ₃ may be determined. It should be noted that the third oxide voltage Vₒₓ₃, which is the voltage across the third oxide layer 140, may not be equal to the third oxidation potential applied between the electrode 203 and the test region 115 during the third oxidation period. This is because there may be a third external resistance across which a third external voltage drop may develop. The third external voltage drop may be determined by multiplying the third oxidation current with the third external resistance, and it may be deducted from the third oxidation potential to determine Vₒₓ₃. Once Vₒₓ₃ is determined, the value of d₃ may be calculated using the relationship d₃=K₂ (Vₒₓ₃−Vₒₓ₂). This is because the compositional ratio near the second top surface where oxidation is initiated is R₂ (see FIG. 4) and the K_{R} value corresponding to this composition is K₂ (see FIG. 5). It should be noted that the first external resistance, the second external resistance and the third external resistance may be the same or they may be different since resistance at electrolyte/electrode interfaces may be a function of current passing.

Once the values for d₁, d₂ and d₃ are established using the teachings of these inventions, the electrical properties or parameters of the first slice of the graded film, the second slice of the graded film and the third slice of the graded film that were consumed and converted into oxide can be calculated. This procedure may be repeated for other slices of the graded film as oxidation moves deeper. The electrical properties determined for each slice may than be plotted as a function of depth, providing electrical property depth profiles. It should be noted that none of the dimensions or values of variables shown in the figures described above are drawn to scale. Dimensions and values of variables may be exaggerated for ease of explanation of the present inventions. For example, typical number of oxidation steps used to obtain a depth profile through a 200 Å thick film may be 50 or more, and only a few Å thick material may be converted into oxide during each oxidation step. Consequently, one may assume the value of K_{R} to be constant within a given oxidation step during which only a few Å of material is converted into oxide.

The above-mentioned procedures may be applied to any graded film structure where the composition may change as a function of depth through the film. For example, if the graded film under study comprises dissimilar material layers, such as a metal/semiconductor stack structure, a conversion factor for the metal layer may be very different from another conversion factor for the semiconductor layer. An example of this is shown in FIG. 6, where Kₘ represents the conversion factor for the metal layer, and Kₛ represents the conversion factor for the semiconductor layer of the stack structure. L is the thickness of the metal layer. To depth profile this structure, the profiling tool software may have the predetermined values of Kₘ and Kₛ, the thickness of the metal layer and the information about the order of the materials in the stack, i.e. the metal on top of the semiconductor. Oxidation and measurement steps may be carried out during oxidation and measurement periods as described before, until substantially all the metal thickness is converted into oxide using the conversion factor of Kₘ. This end point may be reached at an oxide voltage, Vₒₓₘ, where Vₒₓₘ may be equal to the known thickness, L, of the metal layer divided by Kₘ. Oxidation and measurement steps may then continue into the semiconductor layer and the value of the conversion factor may be changed from Kₘ to Kₛ for determination of thicknesses of each slice of the semiconductor that gets oxidized during each oxidation period. This way a depth profile of the electrical properties of the metal as well as the semiconductor may be obtained.

In a preferred embodiment the profiling tool may automatically change a process solution delivered to the test region when the composition of the film changes. Referring to the example in FIG. 6, a process solution required to oxidize the metal layer may be different than a process solution required to oxidize the semiconductor layer. In this case, the tool may provide a metal process solution during the oxidation steps carried out for the metal layer, but it may switch to a semiconductor process solution once all the metal is converted into oxide, i.e. when the oxide voltage Vₒₓₘ is reached, and oxidation of the semiconductor layer may be initiated.

Therefore, according to the above, some examples of the disclosure are directed to a method of obtaining a depth profile of an electrical property through a film with an original top surface and a composition varying as a function of depth, the method comprising the steps of: measuring the property for the film at a test region, forming a first oxide layer by converting a first slice of the film into oxide at the test region, leaving behind a first residual film, the first slice having a first thickness and the first residual film having a first top surface, measuring the property for the first residual film, forming a second oxide layer by converting a second slice of the film into oxide at the test region, leaving behind a second residual film, the second slice having a second thickness and the second residual film having a second top surface, measuring the property for the second residual film, and determining the property for the first slice and the second slice using the first thickness and the second thickness. Additionally, or alternatively to one or more of the examples above, in some examples, the first thickness is calculated using a first conversion factor corresponding to the composition near the original top surface and the second thickness is calculated using a second conversion factor corresponding to the composition near the first top surface. Additionally, or alternatively, to one or more of the examples above, the second conversion factor is different than the first conversion factor. Additionally, or alternatively, to one or more of the examples above, in some examples, forming the first oxide layer comprises delivering a first process solution onto the test region, the first process solution also touching an electrode, applying a first oxidation potential between the test region and the electrode during a first oxidation period, thus establishing a first oxide voltage across the first oxide layer, and forming the second oxide layer comprises delivering a second process solution onto the test region, the second process solution also touching the electrode, and applying a second oxidation potential between the test region and the electrode, during a second oxidation period, thus establishing a second oxide voltage across the second oxide layer. The first thickness is then calculated by multiplying the first conversion factor by the first oxide voltage, and the second thickness is calculated by multiplying the second conversion factor by a difference between the second oxide voltage and the first oxide voltage. Additionally, or alternatively to one or more of the examples above, in some examples, applying the first oxidation potential during the first oxidation period produces a first oxidation current that passes through the first oxide layer and a first external resistance, generating a first external voltage drop across the first external resistance, and applying the second oxidation potential during the second oxidation period produces a second oxidation current that passes through the second oxide layer and a second external resistance, generating a second external voltage drop across the second external resistance. The first oxide voltage is then determined by subtracting the first external voltage drop from the first oxidation potential, and the second oxide voltage is determined by subtracting the second external voltage drop from the second oxidation potential. Additionally or alternatively to one or more of the examples above, in some examples, the method further comprises the step of forming a test pattern of the film comprising the test region and two or more electrical contact regions outside the test region, which are used to apply the oxidation potentials to the test region and to apply the voltages and currents to the test region for measurement of the electrical property for the residual films. Additionally, or alternatively to one or more of the examples above, in some examples, the film comprises a semiconductor alloy and the second process solution is the same as the first process solution. Additionally, or alternatively to one or more of the examples above, in some examples, the film comprises a (material 1)/(material 2) stack, where material 1 is different than material 2, and the first process solution is used during oxidation periods when slices of material 1 are converted into oxide, and the second process solution, which is different from the first process solution, is used during oxidation periods when slices of material 2 are converted into oxide. Additionally, or alternatively to one or more of the examples above, in some examples, the (material 1)/(material 2) stack is a metal/semiconductor stack, or a semiconductor/semiconductor stack.

Some examples of the disclosure are directed to a method of obtaining a depth profile of an electrical property through a film with an original top surface and a composition varying as a function of depth, comprising the steps of: forming a test pattern of the film comprising a test region and two or more electrical contact regions outside the test region, electrochemically oxidizing the film in successive oxidation steps leaving behind residual films, measuring the electrical property of the residual films, determining oxide voltages across each oxide layer formed during each oxidation step, determining thicknesses of the film slices converted into oxide during each oxidation step using the oxide voltage value at that step and a conversion factor corresponding to the composition of the film slice getting converted into oxide, and calculating the property for each of the film slices. Additionally, or alternatively to one or more of the examples above, in some examples, the method further comprises the steps of predetermining composition versus depth and conversion factor versus composition relationships for the film.

Although the foregoing description has shown, illustrated and described various embodiments of the present inventions, it will be apparent that various substitutions, modifications and changes to the embodiments described may be made by those skilled in the art without departing from the spirit and scope of the present inventions.

We claim:

1. A method of obtaining a depth profile of an electrical property through a film with an original top surface and a composition varying as a function of depth, the method comprising the steps of:
measuring the electrical property for the film at a test region,
forming a first oxide layer by converting a first slice of the film into oxide at the test region, leaving behind a first residual film, the first slice having a first thickness and the first residual film having a first top surface,
measuring the electrical property for the first residual film,
forming a second oxide layer by converting a second slice of the film into oxide at the test region, leaving behind a second residual film, the second slice having a second thickness and the second residual film having a second top surface,
measuring the electrical property for the second residual film, and
determining the electrical property for the first slice and the second slice using the first thickness and the second thickness,
wherein the first thickness is calculated using a first conversion factor corresponding to the composition near the original top surface and the second thickness is calculated using a second conversion factor corresponding to the composition near the first top surface.

2. The method of claim 1, wherein the second conversion factor is different from the first conversion factor.

3. The method of claim 2, wherein forming the first oxide layer comprises delivering a first process solution onto the test region, the first process solution also touching an electrode, applying a first oxidation potential between the test region and the electrode during a first oxidation period, thus establishing a first oxide voltage across the first oxide layer, and
wherein forming the second oxide layer comprises delivering a second process solution onto the test region, the second process solution also touching the electrode, and applying a second oxidation potential between the test region and the electrode during a second oxidation period, thus establishing a second oxide voltage across the second oxide layer.

4. The method of claim 3, wherein the first thickness is calculated by multiplying the first conversion factor by the first oxide voltage, and wherein the second thickness is calculated by multiplying the second conversion factor by a difference between the second oxide voltage and the first oxide voltage.

5. The method of claim 4, wherein applying the first oxidation potential during the first oxidation period produces a first oxidation current that passes through the first oxide layer and a first external resistance, generating a first external voltage drop across the first external resistance.

6. The method of claim 5, wherein applying the second oxidation potential during the second oxidation period produces a second oxidation current that passes through the second oxide layer and a second external resistance, generating a second external voltage drop across the second external resistance.

7. The method of claim 6, wherein the first oxide voltage is determined by subtracting the first external voltage drop from the first oxidation potential, and the second oxide voltage is determined by subtracting the second external voltage drop from the second oxidation potential.

8. The method of claim 7 further comprising the step of forming a test pattern comprising the test region before the step of measuring the electrical property for the film, wherein the test pattern also comprises two or more electrical contact regions configured such that entirety of an electric test current passing between any two electrical contact regions passes through the test region, and wherein the two or more electrical contact regions are outside the test region.

9. The method of claim 8 wherein the electrical property is at least one of sheet resistance, sheet Hall coefficient, resistivity, mobility and carrier concentration.

10. The method of claim 9 wherein the film comprises an alloy.

11. The method of claim 10 wherein the alloy is SiGe.

12. The method of claim 9, wherein the film comprises a stack of dissimilar material layers.

13. The method of claim 12, wherein the second process solution is different from the first process solution.

14. The method of claim 13 wherein the stack is one of a metal/semiconductor structure and a semiconductor/semiconductor structure.
